(19) United States
(12) Patent Application Publication
(10) Pub. No.: US 2007/0177439 A1
(43) Pub. Date: Aug. 2, 2007

(54) Displaying supply information of an image forming apparatus

(76) Inventors: Yuka Saito, Kanagawa (JP); Yasuyuki Igarashi, Kanagawa (JP); Toshio Kitazawa, Chiba (JP); Yoshiya Inoue, Kanagawa (JP); Takeshi Fujita, Tokyo (JP); Hiroshi Gotoh, Tokyo (JP)

Correspondence Address: DICKSTEIN SHAPIRO LLP, 1825 EYE STREET NW, Washington, DC, 20006-5403, US

(21) Appl. No.: 11/699,507

(22) Filed: Jan. 30, 2007

(30) Foreign Application Priority Data
Jan. 31, 2006 (JP) 2006-023848
Mar. 16, 2006 (JP) 2006-072429

(51) Int. Cl. G11C 7/00

(52) U.S. Cl. 365/190

(57) ABSTRACT

An apparatus, method, system, computer program and product, each capable of managing supply information of an image forming device provided in an image forming apparatus, and displaying the supply information.

### CROSS-REFERENCE TO RELATED APPLICATIONS

This patent application is based on and claims priority under 35 U.S.C. §119 to Japanese patent application Nos. 2006-023848, filed on Jan. 31, 2006, and 2006-072429 filed on Mar. 16, 2006, in the Japanese Patent Office, the entire contents of which are hereby incorporated by reference.

1. Field of the Invention

Example embodiments of the present invention relate generally to an apparatus, method, system, computer program and product, each capable of managing supply information of an image forming device provided in an image forming apparatus, and displaying the supply information.

2. Description of the Related Art

The background image forming apparatus, such as a printer, copier, etc., often provides the function of notifying a user when a supply of the image forming apparatus needs to be replaced, i.e., the supply is in the end state, and/or notifying the user when a supply of the image forming apparatus needs to be replaced soon, i.e., the supply is in the near end state.

However, since notification is automatically output only when the supply is in the near end state or end state, the user may not be given enough time to replace with a new supply or order a new supply. Further, since notification is usually output for one supply at a time, it may increase work of the user especially when timing for outputting notification for a first supply and timing for outputting notification for a second supply occur in a short time period. Further, timing at which the user prefers to replace with a new supply or order a new supply, or timing at which the user prefers to have information regarding a supply, may differ among users or under various situations.

On the other hand, in order to provide supply information to the user, the image forming apparatus is usually required to be in an operation mode even when image forming is not performed, for example, as described in the Japanese Patent Application Publication No. 2003-316218. If the user requests for supply information when the image forming apparatus is in an energy save mode, the image forming apparatus is brought back to the operation mode. For this reason, electricity consumption may increase if the function of providing supply information is provided.

### SUMMARY

Example embodiments of the present invention include an apparatus, method, system, computer program and product, each capable of storing supply information of an image forming device provided in the apparatus in a corresponding manner with display settings information, updating the supply information to generate updated supply information when updating of the supply information is detected, and generating a supply information screen including the updated supply information for display according to the display settings information. The contents or appearance of the supply information screen, or timing for displaying the supply information screen may be set according to the display settings information that may be input by a user.

In one example, the display settings information may be set such that the supply information screen including the updated supply information is automatically displayed when updating of the supply information is detected.

In another example, the display settings information may be set such that a selection key allowing the user to select whether to display the supply information screen including the updated supply information is automatically displayed when updating of the supply information is detected.

In another example, the display settings information may be set such that the supply information screen including supply status information indicating that the image forming device is in the near end state, with a level of the near end state being defined by the user.

Other example embodiments of the present invention include an apparatus, method, system, computer program and product, each capable of displaying supply information of an image forming device provided in the apparatus without causing the apparatus to be in the operation mode.

In one example, when the apparatus is determined to be in an energy save mode, supply information that is stored in the apparatus, such as the last-updated supply information, may be displayed.

In another example, when the apparatus is determined to be in the energy save mode, electric power is supplied to a selected portion of the apparatus that is necessary for obtaining updated supply information without bring the apparatus back to the operation mode.

In addition to the above-described example embodiments, the present invention may be practiced in various other ways.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a schematic block diagram illustrating the hardware structure of a printer controller and its surroundings, provided in an image forming apparatus, according to an example embodiment of the present invention;

FIG. 2 is a schematic block diagram illustrating the structure of a selected portion of a printer engine of the image forming apparatus shown in FIG. 1, according to an example embodiment of the present invention;

FIG. 3 is a schematic block diagram illustrating the structure of an image forming unit shown in FIG. 2, according to an example embodiment of the present invention;

FIG. 4 is a schematic block diagram illustrating the structure of a transfer device shown in FIG. 2, according to an example embodiment of the present invention;

FIG. 5 is a schematic block diagram illustrating the software structure of a selected portion of the printer controller shown in FIG. 1, according to an example embodiment of the present invention;

FIG. 6 is a schematic block diagram illustrating the software structure of a display module shown in FIG. 5, according to an example embodiment of the present invention;

FIG. 7 is a flowchart illustrating operation of displaying supply information, according to an example embodiment of the present invention;

FIG. 8 is a flowchart illustrating operation of updating supply information, according to an example embodiment of the present invention;

FIG. 9 is a supply management table storing supply information and display settings information, according to an example embodiment of the present invention;

FIG. 10 is a supply management table storing supply information and display settings information, according to an example embodiment of the present invention;

FIG. 11 is a flowchart illustrating operation of displaying supply information, according to an example embodiment of the present invention;

FIG. 12 is a flowchart illustrating operation of generating a supply information screen, according to an example embodiment of the present invention;

FIG. 13 is an example supply management table storing supply information and display settings information, according to an example embodiment of the present invention;

FIG. 14 is an example supply information screen displayed by the image forming apparatus shown in FIG. 1, according to an example embodiment of the present invention;

FIG. 15 is an example wait screen displayed by the image forming apparatus shown in FIG. 1, according to an example embodiment of the present invention;

FIG. 16 is an example icon indicating the legitimacy of a printer supply, displayed by the image forming apparatus shown in FIG. 1;

FIG. 17 is an example wait screen displayed by the image forming apparatus shown in FIG. 1, according to an example embodiment of the present invention;

FIG. 18 is an example supply information screen displayed by a display device that is communicatable with the image forming apparatus shown in FIG. 1, according to an example embodiment of the present invention;

FIG. 19 is an example display settings screen displayed by the image forming apparatus shown in FIG. 1, according to an example embodiment of the present invention;

FIG. 20 is an example display settings screen displayed by the image forming apparatus shown in FIG. 1, according to an example embodiment of the present invention;

FIG. 21 is an example printing settings screen displayed by the image forming apparatus shown in FIG. 1, according to an example embodiment of the present invention;

FIG. 22 is a schematic block diagram illustrating an example functional structure of the image forming apparatus shown in FIG. 1, according to an example embodiment of the present invention;

FIG. 23 is a schematic block diagram illustrating an example functional structure of the image forming apparatus shown in FIG. 1, according to an example embodiment of the present invention;

FIG. 24 is a flowchart illustrating operation of displaying supply information, according to an example embodiment of the present invention;

FIG. 25 is an example table storing power supply information, stored by the image forming apparatus shown in FIG. 23;

FIG. 26 is a flowchart illustrating operation of displaying supply information, according to an example embodiment of the present invention;

FIG. 27 is a flowchart illustrating operation of displaying supply information, according to an example embodiment of the present invention;

FIG. 28 is a schematic block diagram illustrating the hardware structure of an image forming apparatus having the functional structure shown in FIG. 23, according to an example embodiment of the present invention; and

FIG. 29 is a flowchart illustrating operation of displaying supply information, according to an example embodiment of the present invention.

### DETAILED DESCRIPTION OF THE INVENTION

In describing the example embodiments illustrated in the drawings, specific terminology is employed for clarity. However, the disclosure of this patent specification is not intended to be limited to the specific terminology selected and it is to be understood that each specific element includes all technical equivalents that operate in a similar manner. For example, the singular forms “a”, “an” and “the” are intended to include the plural forms as well, unless the context clearly indicates otherwise.

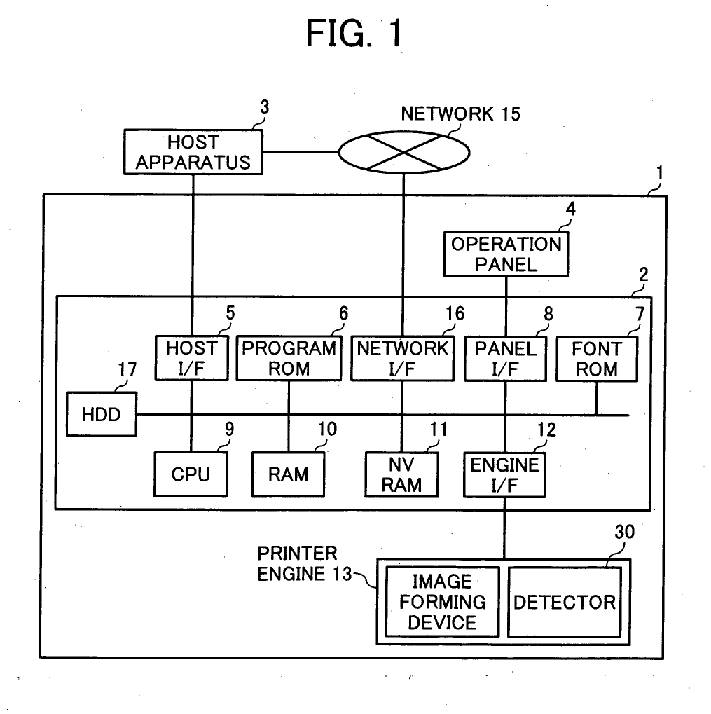

Referring now to the drawings, wherein like reference numerals designate identical or corresponding parts throughout the several views, FIG. 1 illustrates an image forming apparatus 1 according to an example embodiment of the present invention. The image forming apparatus 1 may be connected to a host apparatus 3 through a local area network (LAN). The host apparatus 3 may be implemented by a general-purpose computer, which may be provided with a display device and an input device. The image forming apparatus 1 may be further connected to a network 15, such as the Internet. In this example, the image forming apparatus 1 is implemented by a printer capable of printing data received from the outside or stored in the image forming apparatus 1. However, the image forming apparatus 1 may be implemented, for example, as a copier capable of copying an original, or a multifunctional apparatus (MFP) capable of performing one or more functions of scanning, faxing, copying, printing, and communicating via a network, as long as it is capable of outputting supply information, such as supply amount information and/or supply status information, as described below. When the image forming apparatus 1 is implemented by a scanner or MFP, other devices, such as a scanner engine, a scanner device, or a document feeder, may be additionally provided. For the descriptive purpose, in this specification, the image forming apparatus 1 may be referred to as the printer 1.

As illustrated in FIG. 1, the printer 1 includes a printer controller 2, an operation panel 4, and a printer engine 13.

The printer controller 2 converts print data, which may be received from the host apparatus 3 or the network 15, to video data according to an operation mode, and outputs the video data to the printer engine 13. The operation mode may be set by the printer 1 using a printer driver. Alternatively, the operation mode may be set by the host apparatus 3 or any apparatus provided on the network 15 using a printer driver, and sent to the printer controller 2 together with the print data. As illustrated in FIG. 1, the printer controller 2 includes a host interface (I/F) 5, a program read only memory (ROM) 6, a font ROM 7, a panel I/F 8, a central processing unit (CPU) 9, a random access memory (RAM) 10, a non-volatile (NV) RAM 11, an engine I/F 12, a network I/F 16, and a hard disk drive (HDD) 17, which are connected through a bus.

The CPU 9 may function as a system controller, which controls various kinds of operation performed by the printer 1, for example, printing, communicating with the outside apparatus, communicating with the user through the operation panel 4, managing supply information, etc. For example, when performing printing operation, the CPU 9 processes or manages data, including, for example, print data, or control data including the operation mode, which may be received from the host apparatus 3 or the network 15. In another example, when performing supply management operation, the CPU 9 manages supply information, including supply amount information and supply status information, which may be obtained from the printer engine 13.

The CPU 9 may be provided with one or more memories, each of which may function as, for example, a system memory, a flame memory, a parameter memory, a program memory, or a font memory. In this example, the program ROM 6, the font ROM 7, the RAM 10, the NV RAM 11, and the HDD 17 are provided. However, another memory may be optionally provided.

The program ROM 6 stores including, for example, a print control program for causing the CPU 9 to perform printing operation, or a supply management program for causing the CPU 9 to perform operation of managing supply information. Additionally, the program ROM 6 may store a power control program for causing the CPU 9 to perform operation of controlling electric power supplied to a selected portion of the printer 1. The font ROM 7 stores various kinds of fonts for printing. The RAM 10 may function as a work area of the CPU 9, a buffer area for storing print data to be printed on one page of document, a buffer area for storing control data, or a bitmap memory for storing video data converted from the print data. In addition, the RAM 10 may store information indicating whether the printer 1 is in an operation mode or an energy save mode, for example, as described below. The NV RAM 11 stores various data, for example, various parameters that may be used by the printer 1 even after the power of the printer 1 is turned off. For example, as described below, the NV RAM 11 may store supply information, display settings information, and/or printing settings information, in a manner manageable by the CPU 9. The HDD 17 stores a large amount of data, including, for example, print data to be printed, or any kind of program that may be used by the CPU 9.

The CPU 9 may be additionally provided with one or more interfaces, such as the host I/F 5, the network I/F 16, the panel I/F 8, and the engine I/F 12. The host I/F 6 allows the printer controller 2 to communicate with the host apparatus 3, for example, by inputting print data or control data received from the host apparatus 3, or outputting status data, such as supply information, to the host apparatus 3. The host I/F 6 may be implemented by a Universal Serial Bus (USB). The network I/F 16 allows the printer controller 2 to communicate with the network 15, for example, by inputting print data or control data received from the network 15, or outputting status data, such as supply information, to the network 15. Alternatively, the function of the network I/F 16 may be performed, for example, by a network interface controller (NIC) provided in the printer controller 2 and a network I/F provided outside of the printer controller 2. The panel I/F 8 allows the printer controller 2 to communicate with the operation panel 4, for example, by inputting control data received from the operation panel 4, or outputting status data, such as supply information, to the operation panel 4. The engine I/F 12 allows the printer controller 2 to communicate with the printer engine 13, for example, outputting;

control data or video data to the printer engine 13, or inputting status data, such as supply information, received from the printer engine 13. In addition, the CPU 9 may be provided with a medium interface that allows the printer controller 2 to read out data from a removable medium or write data onto the removable medium.

The operation panel 4 has at least one of the functions of outputting status data received from the printer controller 2 to the user, and inputting control data to the printer controller 2 received from the user. For example, the operation panel 4 may include a display device, such as a liquid crystal display (LCD), capable of displaying supply information to a user received from the printer controller 2. Alternatively, the operation panel 4 may include any desired notifying device, as long as it can provide supply information to the user in the form such that the user can easily percept, for example, including a buzzer or a speaker. In this example, the operation panel 4 may further include an input device capable of inputting printing settings information or display settings information from the user, for example, information regarding the operation mode, the font to be used for printing, the initial screen (“waiting screen”) to be displayed by the display device when performing printing, a supply information screen to be displayed by the display device when notifying the supply information, etc. The input device may be implemented by, for example, any number of keys, a keyboard, a ten key, a switch, a pointing device, or a microphone. Alternatively, the operation panel 4 may be implemented by a touch panel, which provides the functions of displaying and inputting.

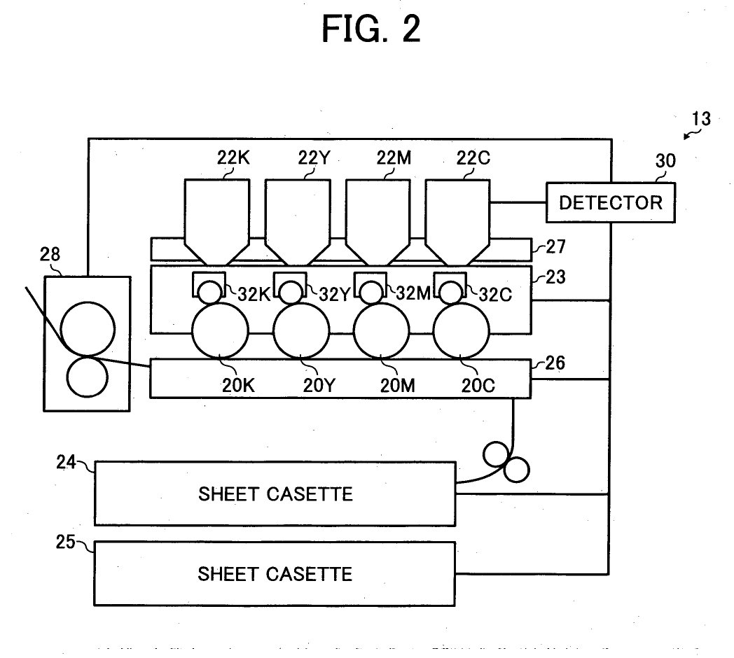

The printer engine 13 includes an image forming device and a detector 30. In one example, the printer engine 13 performs printing operation under control of the printer controller 2, using the image forming device. For example, the printer engine 13 forms a toner image according to the video data and the control data received from the printer controller 2. In another example, the printer engine 13 detects supply information of the image forming device using the detector 30. An example structure of the printer engine 13 is described below referring to any one of FIGS. 2, 3, and 4.

In one example operation, the printer controller 2 causes the printer engine 13 to form a toner image according to print data received from the host apparatus 3 as described below.

First, the CPU 9 obtains data, which includes print data and control data, from the host apparatus 3 through the host I/F 5. The CPU 9 analyzes the received data by loading the print control program from the program ROM 6 onto the RAM 10, extracts the print data and the control data, and stores the print data and the control data in the RAM 10 for further processing. Second, the CPU 9 converts the print data to video data according to the control data. For example, when a character code is extracted, the CPU 9 analyzes the character code, converts the character code into an intermediate code including information regarding the print position, print size, character code, font, etc., and performs processing based on the intermediate code to expand the received data into the RAM 10. The expanded data, which may correspond to one page of document, may be converted to the video data. Third, the printer controller 2 outputs the video data to the printer engine 13, and instructs the printer engine 13 to form a toner image according to the video data through the engine I/F 12.

Referring now to any one of FIG. 2, 3, and 4, the structure of the printer engine 13 is explained according to an example embodiment of the present invention.

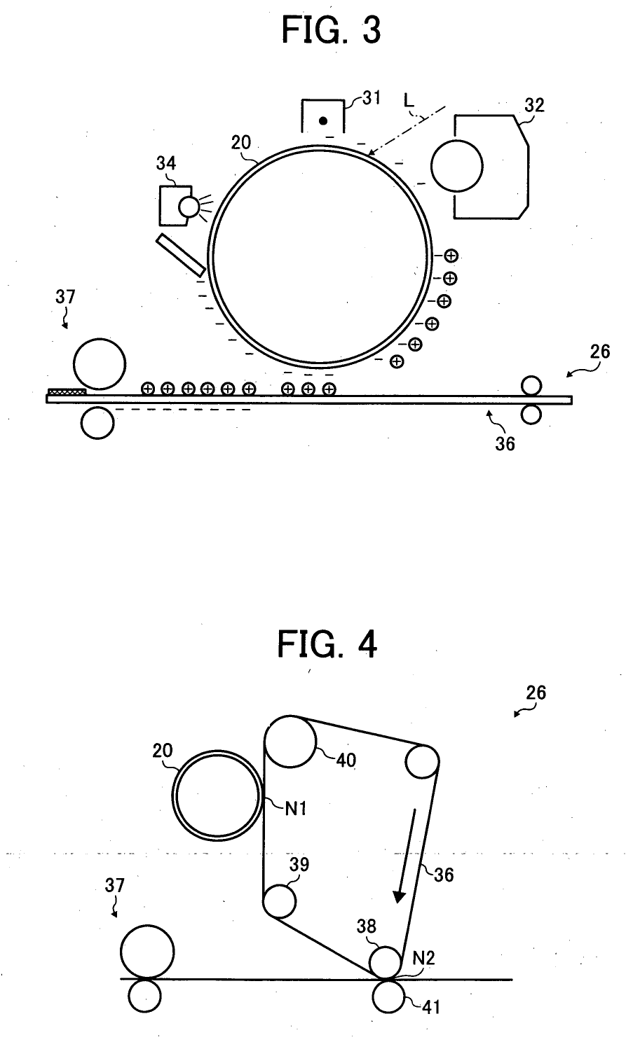

Referring to FIG. 2, the printer engine 13 may include four image forming units 23K, 23Y, 23M, and 23C (collectively referred to as “the image forming unit 23”), four toner cartridges 22K, 22Y, 22M, and 22C (collectively referred to as “the toner cartridge 22”), sheet feeding cassettes 24 and 25, a transfer device 26, an optical writing device 27, a fixing device 28, and the detector 30. In this example, the image forming unit 23 may have the tandem-type structure, which includes four photoconductors 20K, 20Y, 20M, and 20C (collectively referred to as the “photoconductor 20”) for the respective colors of black, yellow, magenta, and cyan. For each of the photoconductors 20K, 20Y, 20M, and 20C, one or more devices are provided, for example, as illustrated in FIG. 3.

As illustrated in FIG. 3, the image forming unit 23 additionally includes a charging device 31, a developing device 32, a cleaning device 33, and a discharging device 34, which are provided in a vicinity of the photoconductor 20.

The charging device 31 uniformly charges the surface of the photoconductor 20 to a predetermined polarity. The optical writing device 27 exposes a modulated light L to the charged surface of the photoconductor 20 to form a latent image on the charged surface of the photoconductor 20. The developing device 32 develops the latent image into a toner image, by applying toner having the reverse of the predetermine polarity. The toner may be provided from the corresponding toner cartridge 22 of FIG. 2. The toner image, formed on the surface of the photoconductor 20, is transferred to the surface of a recording sheet, which may be carried by a transfer belt 36 of the transfer device 26. The recording sheet may be fed by either one of the sheet feeding cassettes 24 and 25 shown in FIG. 2. The cleaning deice 33 removes the residual toner, which may be remained on the surface of the photoconductor 20 after transferring the image, from the surface of the photoconductor 20. The residual toner collected by the cleaning device 33 may be stored in a used toner bottle, not illustrated. The discharging device 34 discharges the charged surface of the photoconductor 20 after transferring the image. The recording sheet having the toner image thereon is further carried by the transfer device 26 to the fixing device 37. When the recording sheet passes through the fixing device 37, the toner image is fixed onto the surface of the recording sheet by heat and pressure. In this example, the fixing device 37 may include a lubricant agent supplying device, not illustrated. When fixing, a lubricant agent, such as oil, may be supplied to the fixing device 37.

In this example, the transfer device 26 may transfer the toner image onto the recording sheet in two steps. As illustrated in FIG. 4, the transfer belt 36 of the transfer device 26 may be implemented by an intermediate transfer belt. In such case, the transfer device 26 may additionally include a drive roller 38, a transfer earth roller 39, a transfer bias roller 40, and a sheet transfer roller 41. The transfer belt 36, which is an endless belt wound around the drive roller 38, the transfer bias roller 40, and the transfer earth roller 39, is driven by the drive roller 38 in the direction indicated by the arrow. The transfer belt 36 is in close contact with the surface of the photoconductor 20 at a first transfer position N1 at which the toner image formed on the surface of the photoconductor 20 is transferred to the surface of the transfer belt 36. The transfer belt 36 is in close contact with the sheet transfer roller 41 at a second transfer position N2 at which the toner image carried by the transfer belt 36 is transferred to the surface of a recording sheet carried by another transfer belt that passes through the nip formed between the rollers 38 and 41. When the recording sheet carrying the toner image passes through the fixing device 37, the toner image is fixed onto the recording sheet by heat and pressure applied by the fixing device 37. The recording sheet having the fixed toner image is discharged from the printer 1 to complete printing operation.

In another example operation, the printer controller 2 manages supply information for display, such as supply amount information or supply status information, regarding the image forming device provided in the printer engine 13. In this example, the supply amount information of the image forming device corresponds to any information, obtainable by the detector 30, which describes the amount of a supply of the image forming device provided in the printer 1 (“the printer supply”), including, for example, the degree of usage of the device, the remaining life time of the device, the amount of consumption of a supply managed by the device, and the remaining amount of the supply managed by the device. In this example, the supply status information corresponds to any information relating to the current status of the printer supply, such as the near end state or the end state of the printer supply. Additionally or alternatively, the supply status information may correspond to information indicating whether the printer supply is a legitimate product that can be warranted by a manufacturer.

In order to obtain supply amount information regarding the photoconductor 20, the detector 30 may be implemented by a counter capable of counting the number of rotations of the photoconductor 20 or a timer capable of counting a time period during when the photoconductor 20 is in operation. In another example, in order to obtain supply amount information regarding the developing device 32, the detector 30 may be implemented by a counter capable of counting the number or rotations of a developing roller or a timer capable of counting a time period during when the developing device 32 is in operation. In another example, in order to obtain supply amount information regarding the transfer device 26, the detector 30 may be implemented by a counter capable of counting the number of rotations of the transfer belt 36 or a timer capable of counting a time period during when the transfer device 26 is in operation. In another example, in order to obtain supply amount information regarding the fixing device 37, the detector 30 may be implemented by a counter capable of counting the number of rotations of a roller provided in the fixing device 37 or a timer capable of counting a time period during when the fixing device 37 is in operation. In another example, in order to obtain supply amount information regarding the toner cartridge 22, the detector 30 may be implemented by a toner sensor capable of detecting the amount of toner remained in the toner cartridge 22. In another example, in order to obtain supply amount information regarding the cleaning device 33, the detector 30 may be implemented by a used toner bottle sensor capable of detecting the amount of used toner stored in the used toner bottle of the cleaning device 33. In another example, in order to obtain supply amount information regarding the fixing device 37, the detector 30 may be implemented by an oil supply sensor capable of detecting the amount of oil remained in the fixing device 37. In another example, in order to obtain supply amount information regarding the sheet feeding cassette 24 or 25, the detector 30 may be implemented by a sheet sensor capable of detecting the amount of sheets remained in the sheet feeding cassette 24 or 25.

For the illustrative purpose, an example operation of obtaining supply amount information regarding the photoconductor 20 using the detector 30 is explained below.

By repeating the image forming operation described above referring to FIG. 3, which may include charging, exposing, developing, transferring, fixing, and cleaning, the surface of the photoconductor 20 may be degraded such that the surface of the photoconductor 20 may be worn or scratched, or photoconductivity may be lowered.

This may cause one or more problems, including lower image quality, abnormal amount of toner consumption, or jamming of a recording sheet. In light of this, the photoconductor 20 is replaced when degradation of the photoconductor 20 is detected.

Further, when degradation of the photoconductor 20 is detected, image forming operation of the printer 1 may be restricted or may not be performed such that further degradation of the photoconductor 20 may be suppressed. In order to obtain supply amount information, the detector 30 counts an accumulated time period in which the photoconductor 20 is driven by a drive motor to obtain a counted time period. Further, in this example, the counted time period may be converted to the number of pages (“the number of printed pages”), using information regarding the counted time period for printing one page of recording sheet. The number of printed pages may be stored in an involatile memory as the supply amount information of the photoconductor 20.

For the illustrative purpose, an example operation of obtaining supply amount information regarding the toner cartridge 22 is explained below.

By repeating the developing operation as described above referring to FIG. 3, toner is consumed. Even when a monochrome or color toner image is not formed on a recording sheet, toner may be consumed as long as the developing device 32 is in operation since the toner may function as a buffering agent to suppress friction generated between the developing device 32 and the photoconductor 20. When all toner stored in the toner cartridge 22 is consumed, a toner image may not be formed with high quality. Additionally, when all toner stored in the toner cartridge 22 is consumed, the photoconductor 20 may be easily degraded due to the friction generated between the developing device 32 and the photoconductor 20. Further, since no toner is applied to the charged surface of the photoconductor 20, the recording sheet may be brought in direct contact with the surface of the photoconductor 20, thus damaging the photoconductor 20 or causing jamming of the recording sheet. In light of this, the toner cartridge 22 is replaced when low toner supply is detected. Further, when lower toner supply is detected, image forming operation of the printer 1 may be restricted or may not be performed such that further toner consumption may be suppressed. In order to obtain supply amount information, the detector 30 detects the amount of toner remained in the toner cartridge 22 (“the remaining toner amount”), for example, by detecting the total weight of toner or detecting the height made by the accumulated toner. The remaining toner amount may be stored in an involatile memory as the supply amount information of the toner cartridge 22.

The supply information detected by the detector 30, such as the supply amount information and the supply status information, may be stored in any desired memory in the form manageable by the printer controller 2. Further, in this example, the display settings information and/or the printing settings information may be stored in the form manageable by the printer controller 2.

In one example, the printer controller 2 may update supply amount information upon receiving notification from the printer engine 13 that supply information is updated. For example, the printer engine 13 sends notification to the printer controller 2 every time the number of printed pages is increased by 10%, with 0% corresponding to the state in which the photoconductor 20 is just installed. In another example, the printer engine 13 sends notification to the printer controller 2 every time the remaining toner amount is decreased by 5%, with 100% corresponding to the state in which the remaining toner amount is full. When notified, the printer controller 2 may update the supply amount information, convert the updated supply amount information in the form perceptible to a user, and display the updated supply amount information. Since the 15 supply amount information is automatically displayed when the supply amount information is updated, the user can easily check whether the printer 1 has enough supply before the supply status information indicating that the printer supply is in the near end or end state is displayed. In another example, when the supply amount information is updated, the printer controller 2 may automatically display a selection key that allows the user to select whether to display the updated supply amount information, or a notification message that the supply amount information is updated.

In another example, the printer controller 2 may update supply status information upon receiving notification from the printer engine 13 that the printer supply is in the near end status or end status. For example, the printer engine 13 sends notification to the printer controller 2 when the number of printed pages reaches a first reference level previously set by the user, such as 45,000 pages, to indicate that the photoconductor 20 is in the near end state. Additionally, the printer engine 13 sends notification to the printer controller 2 when the number of printed pages reaches a second reference level previously set by the user, such as 50,000 pages, to indicate that the photoconductor 20 is in the end state. In another example, the printer engine 13 sends notification to the printer controller 2 when the remaining toner amount reaches a first reference level previously set by the user, such as 15%, to indicate that the toner is in the near end state. Additionally, the printer engine 13 sends notification to the printer controller 2 when the remaining toner amount reaches a second reference level previously set by the user, such as 0%, to indicate that the toner is in the end state. When notified, the printer controller 2 may update the supply status information, convert the updated supply status information in the form perceptible to a user, and display the updated supply status information. Since the reference level for determining the end state or near end state of the printer supply can be changed according to the user preference, the end state or near end state of the printer supply may be detected at timing appropriate for the user. In this example, the reference level for determining the end state of the printer supply is set by the user. Alternatively, the reference level for determining the end state of the printer supply may be preferably set by default.

In another example, the printer controller 2 may update supply status information indicating whether the printer supply is the legitimate product (“legitimacy information”), for example, by detecting identification information provided on the printer supply, such as integrated circuit (IC) chip information. For example, the printer engine 13 may determine whether the toner cartridge 22 is the legitimate product by detecting the IC chip provided on the toner cartridge 22, and send notification to the printer controller 2. When notified, the printer controller 2 may update the legitimacy information, and further convert the legitimacy information to the form perceptible to a user for output. For example, the printer controller 2 may cause any one of the operation panel 4, the host apparatus 3, and a network apparatus existed on the network 15, to notify the user that the illegitimate product is used, for example, by not displaying the supply amount information or by displaying a notification message. In this manner, the use of illegitimate product may be suppressed.

In another example, the printer controller 2 may convert the supply information according to the display settings information. For example, the appearance of supply information may be changed according to the user preference. Alternatively, the contents of supply information for display, such as information indicating which printer supply to display, may be changed according to the user preference. Alternatively, timing for displaying supply information may be changed according to the user preference. In this manner, operability of the printer 1 may be improved.

In another example, the printer controller 2 may obtain supply information from the printer engine 13, upon receiving a request for displaying supply information from any one of the host apparatus 3, the operational panel 4, and the network 15. The obtained supply information, which may be updated at the time of obtaining, may be output for display. Further, the obtained supply information may be printed out on the recording sheet.

In another example, the printer controller 2 may cause the printer 1 to operate differently when the supply status information indicates that the printer supply is in the near end state or end state. For example, when the number of printed pages detected for the photoconductor 20Y is large relative to the number of printed pages detected for the photoconductors 20K, 20M, and 20C, the use of photoconductor 20Y may be suppressed by replacing the red color formed by mixing the yellow color and the magenta color, with the pink color formed by the magenta color. The amount of toner consumption for the yellow color may be suppressed in a substantially similar manner.

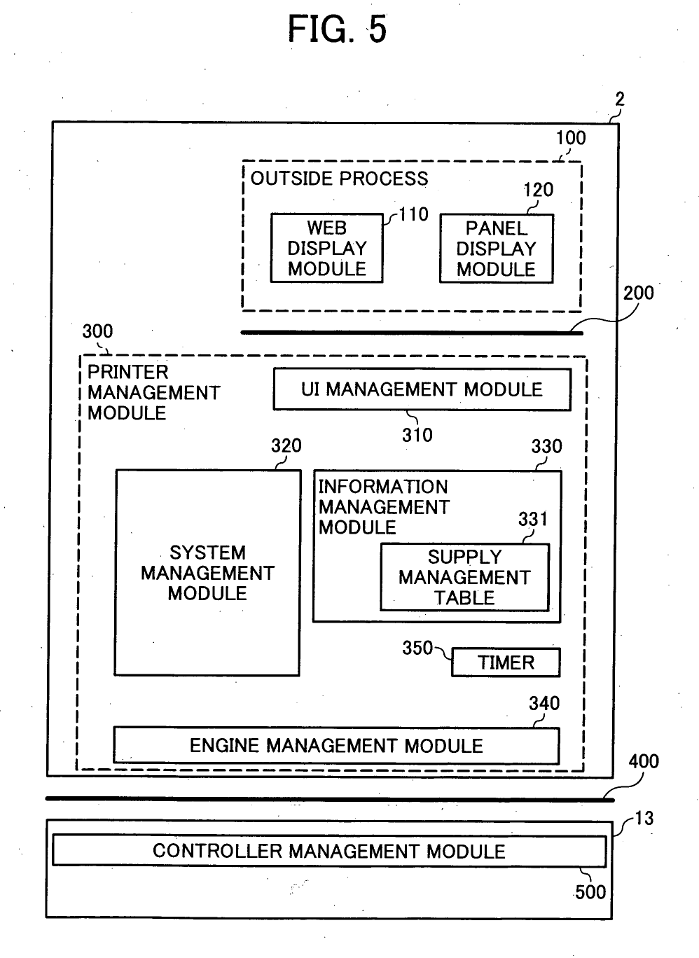

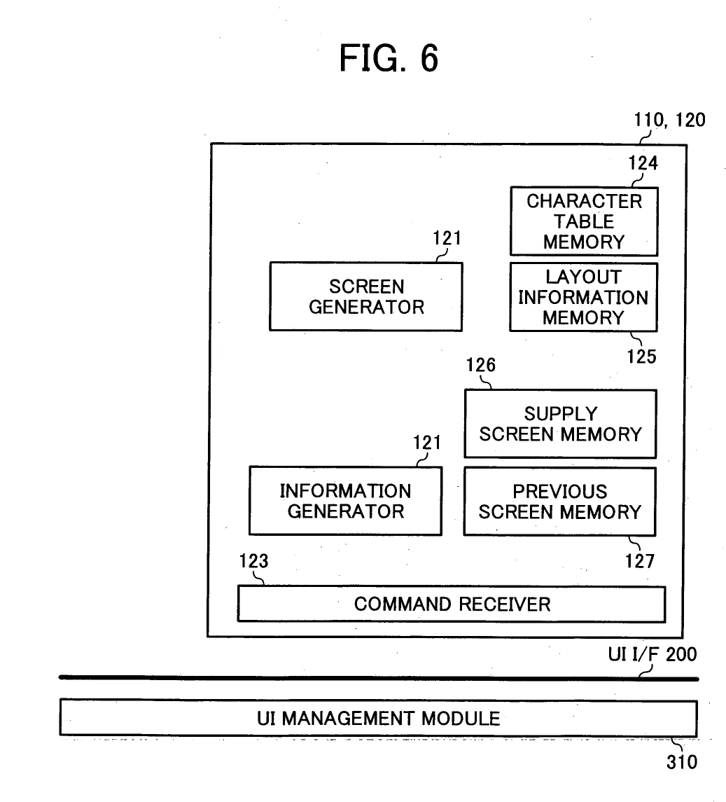

Referring now to FIGS. 5 and 6, an example software structure of the printer controller 2 is explained. Referring to FIG. 5, the printer controller 2 includes a printer management module 300, and an outside process 100.

The printer management module 300 manages status of the printer 1, for example, by updating supply information or obtaining supply information, using one or more peripheral modules. The printer management module 300 includes a user interface (UI) management module 310, a system management module 320, an information management module 330, an engine management module 340, and a timer 350. The printer management module 300 is coupled to the outside process 100 via a UI I/F 200, and to a controller management module 500 of the printer engine 13 via an engine controller I/F 400.

The system management module 320 may have the function of receiving a request or response, sending a request or response, or determining whether the printer 1 is performing printing operation. The information management module 330 may have the function of managing various information regarding a printer supply stored in a supply management table 331, such as supply amount information, supply status information, display settings information, printing settings information, user ID information, etc. The UI management module 310 manages communication between the printer management module 300 and the outside process 100 via the UI I/F 200, which includes a web display module 110 and/or a panel display module 120. The engine management module 340 manages communication between the printer management module 300 and the printer engine 13 via the engine controller I/F 400. The timer 350, which may be optionally provided, counts a time period from predetermined timing to generate a counted time period, which may be used by the system management module 320.

As illustrated in FIG. 6, the web display module 110 and the panel display module 120 may each include a screen generator 121, information generator 122, command receiver 123, character table memory 124, layout information memory 125, supply screen memory 126, and previous screen memory 127. The command receiver 123 is coupled to the UI management module 310 of FIG. 5 via the UI I/F 200. The web display module 110 or the panel display module 120 may have a structure different from the structure shown in FIG. 6. For example, a memory for storing user identification (ID) information may be additionally provided.

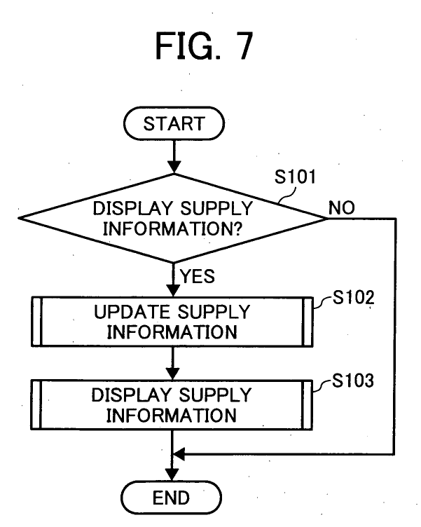

Referring now to FIG. 7, an example operation of displaying supply information, performed by the printer management module 300, is explained.

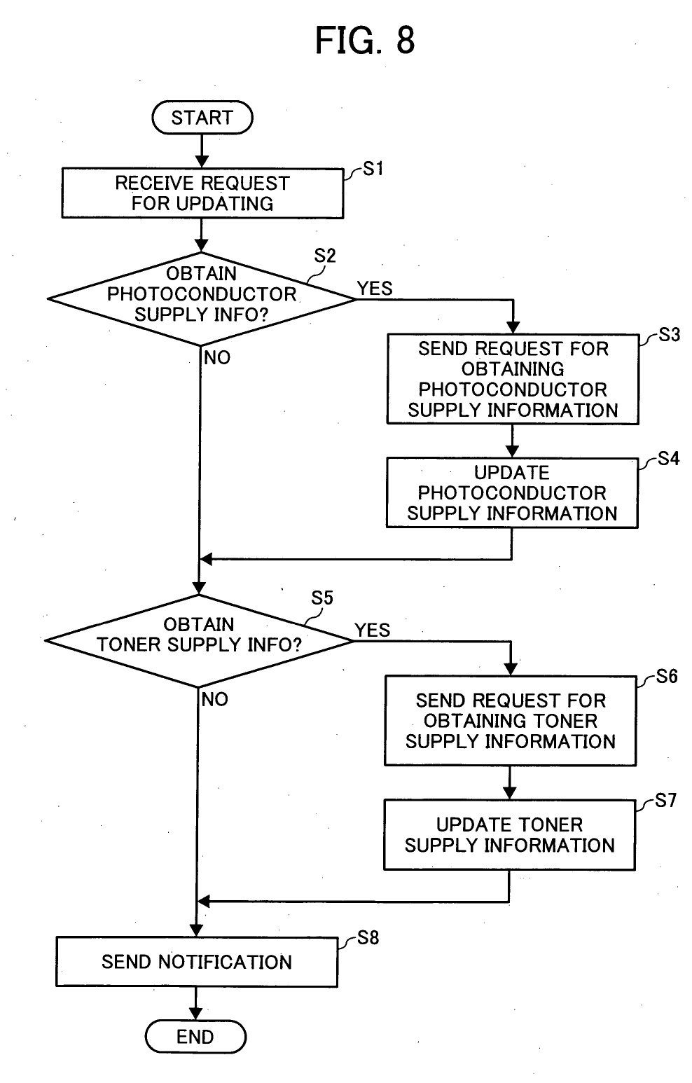

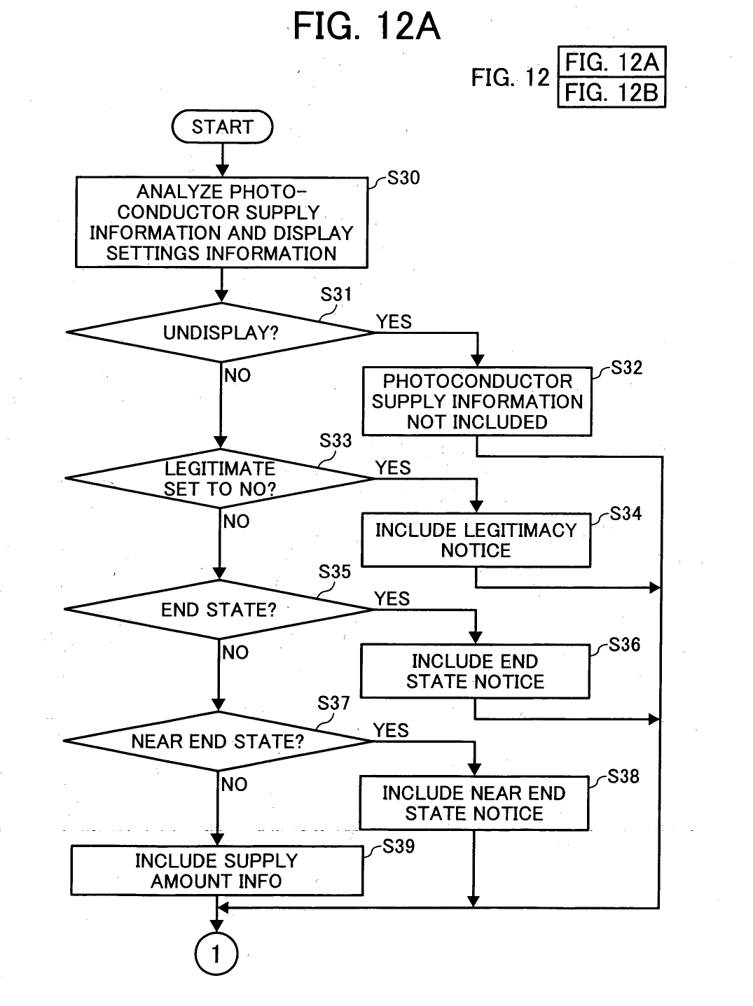

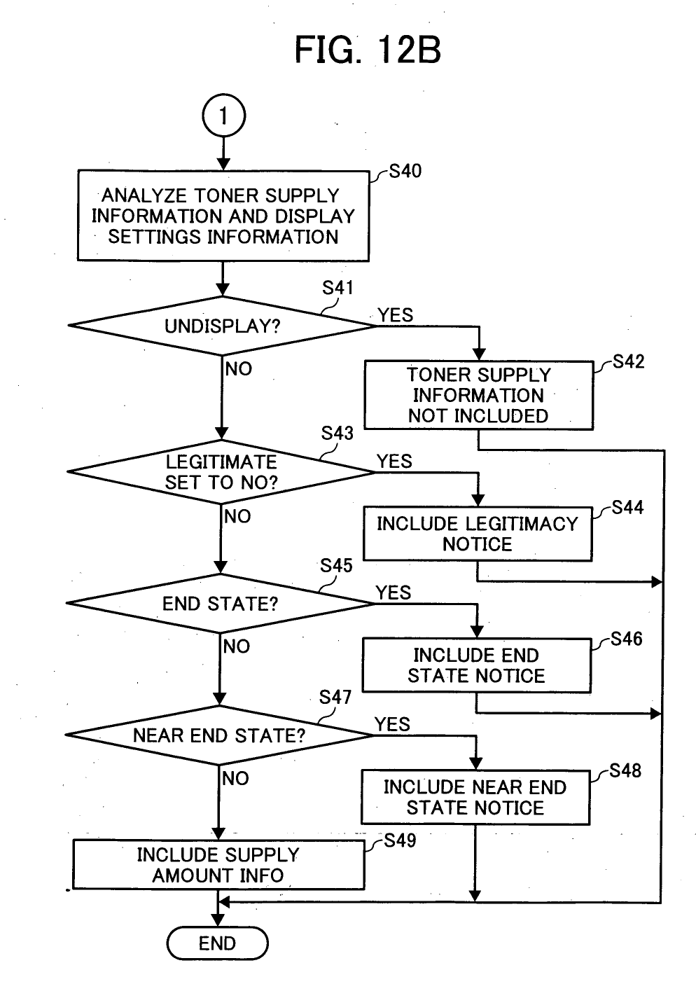

S101 determines whether to display supply information. In one example, the printer management module 300 determines to perform operation of displaying supply information when notification is received from the printer engine 13 that supply information is updated. In another example, the printer management module 300 determines to perform operation of displaying supply information when a request for displaying is received from the outside process 100, such as a user instruction received through the display module 110 or 120. If it is determined to perform operation of displaying (“YES” at S101), the operation proceeds to S102. Otherwise (“NO” at S101), the operation ends. S102 updates supply information stored in the supply management table 331, for example, as described below referring to FIG. 8. S3 displays the updated supply information after converting the updated supply information in the form perceptible to the user according to display settings information, for example, as described below referring to FIGS. 11 and 12, and the operation ends.

Referring now to FIG. 8, an example operation of updating supply information is explained. The operation of FIG. 8 may be performed by the information management module 330 of FIG. 5 under control of the system management module 320.

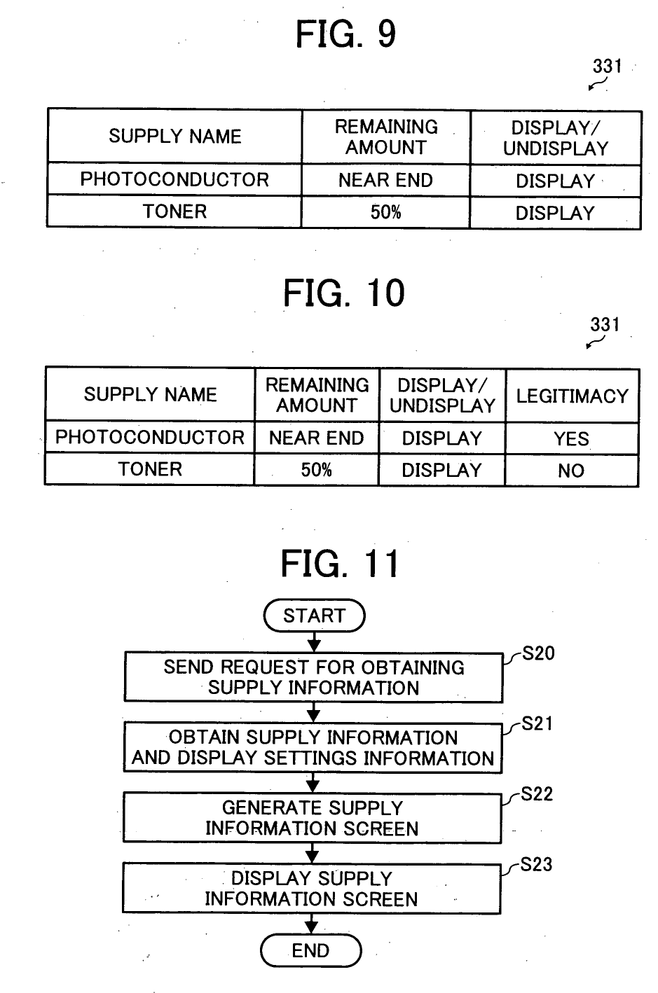

S1 receives a request for updating supply information, which is stored in the supply management table 331, from the system management module 320. In one example, the request may be output by the system management module 320, when updating of supply information is notified by the engine 13 via the engine management module 340 and the engine controller I/F 400. In another example, the request may be output by the system management module 320, when the outside process 100 sends a request for displaying supply information via the UI management module 310 and the UI I/F 200. Further, it is assumed that, in this example, the supply information corresponds to supply information of the photoconductor 20 and supply information of the toner cartridge 22, each of which may be obtained as described above. As illustrated in FIG. 9, in this example, the supply management table 331 may store a supply name, remaining supply amount, and display settings information indicating whether to automatically display supply information (“display/undisplay information) when the supply information is updated, respectively for the photoconductor 20 and the toner cartridge 22.

S2 determines whether to output a request for obtaining supply information of the photoconductor 20 from the printer engine 13, to the printer engine 13 via the engine management module 340. In this example, the information management module 330 may store the display/undisplay information as shown in FIG. 9. The display/undisplay information may be set by default or according to the user preference.

When the display/undisplay information indicates that supply information can be displayed (“YES” at S2), the operation proceeds to S3. Otherwise (“NO” at S2), the operation proceeds to S5.

S3 instructs the engine management module 340 to output a request for obtaining supply information of the photoconductor 20 from the printer engine 13, to the printer engine 13, via the system management module 320. Upon receiving the request, the printer engine 13 sends the updated supply information to the printer management module 300.

S4 updates supply information stored in the supply management table 331 using the supply information obtained at S3.

S5 determines whether to output a request for obtaining supply information of the toner cartridge 22 from the printer engine 13, to the printer engine 13 via the engine management module 340, in a substantially similar manner as described above referring to S2. When the display/undisplay information indicates that supply information is to be displayed (“YES” at S5), the operation proceeds to S6. Otherwise (“NO” at S5), the operation proceeds to S8.

S6 instructs the engine management module 340 to output a request for obtaining supply information of the toner cartridge 22 from the printer engine 13, to the printer engine 13, via the system management module 320. Upon receiving the request, the printer engine 13 sends the updated supply information to the printer management module 300.

S7 updates supply information stored in the supply management table 331 using the supply information obtained at S6.

S8 sends notification that updating operation is completed to the system management module 320, and the operation ends.

The operation of FIG. 8 may be performed in various other ways. For example, the above-described steps may be performed in a different order such that the toner supply information is obtained before obtaining the photoconductor supply information.

In another example, when the display/undisplay information is not stored in the supply management table 330, the information management module 330 may request the system management module 320 for the display/undisplay information.

Alternatively, the information management module 330 may request the system management module 320 for the display/undisplay information upon receiving notification from the system management module 320 that the display/undisplay information is updated through the display module 110 or 120.

In another example, the supply management table 331 may additionally store information other than information shown in FIG. 9. For example, as illustrated in FIG. 10, the supply management table 331 may additionally store supply status information indicating whether the supply is legitimate (“legitimacy information”). In this example, the legitimacy information may be treated as display/undisplay information when performing updating operation, such that once the legitimacy information is stored in the supply management table 331, it is not necessary to update the legitimacy information unless notification is received from the system management module 320.

Referring now to FIGS. 11 and 12, an example operation of displaying supply information is explained. The operations of FIGS. 11 and 12 may be both performed by the web display module 110 or the panel display module 120.

Referring to FIG. 11, S20 sends a request for obtaining supply information to the printer management module 300 via the UI I/F 200. Upon receiving the request, the system management module 320 may send supply information obtained from the information management module 330. At this time, the system management module 320 may request the information management module 330 to update the supply information. Similarly, the system management module 320 may request the information management module 330 to update the display settings information.

S21 obtains the supply information, which may be preferably updated, for one or more printer supplies from the printer management module 300. Additionally, the display settings information is obtained in a corresponding manner with the supply information.

S22 generates a supply information screen including the supply information obtained at S21 according to the display settings information obtained at S21, for example, as described below referring to FIG. 12.

S23 displays the supply information screen, and the operation ends.

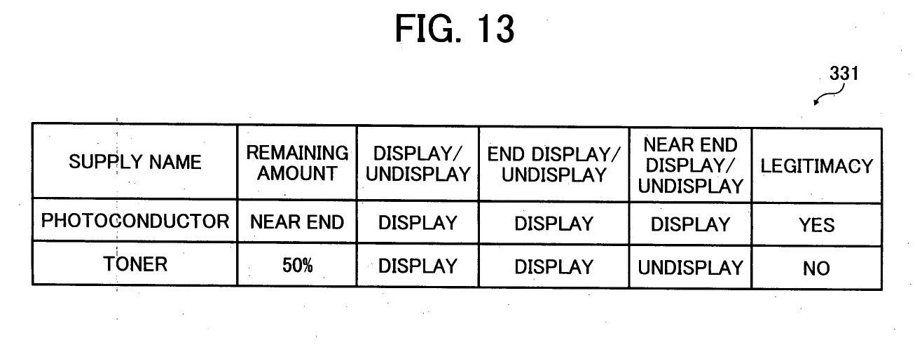

Referring to FIG. 12, operation of generating a supply information screen according to display settings information, performed by the display panel 110 or 120, is explained. In this example, it is assumed that supply information and display settings information are obtained respectively for the photoconductor 20 and the toner cartridge 22. Further, as illustrated in FIG. 13, it is assumed that the supply management table 331 stores various information including the supply name, the remaining amount, display/undisplay information, display settings information indicating whether to automatically notify the end state of the printer supply (“end display/undisplay information”), display settings information indicating whether to automatically notify the near end state of the printer supply (“near end display/undisplay information”), and legitimacy information.

Referring to FIG. 12, S30 analyzes supply information and display settings information, which are obtained for the photoconductor 20.

S31 determines whether the display/undisplay information is set to “UNDISPLAY”. If the display/undisplay information is set to “UNDISPLAY” (“YES” at S31), the operation proceeds to S32 to determine not to include the photoconductor supply information in the supply information screen, and further to S40. If the display/undisplay information is set to “DISPLAY” (“NO” at S31), the operation proceeds to S33.

S33 determines whether legitimacy information for the photoconductor 20 is set to “NO”, i.e., the photoconductor 20 is determined to be the illegitimate product. If legitimacy information is set to “NO” (“YES” at S33), the operation proceeds to S34 to determine to include notification that the photoconductor 20 is not legitimate in the supply information screen, and further to S40. If legitimacy information is set to “YES” (“NO” at S33), the operation proceeds to S35.

S35 determines whether photoconductor supply information indicates that the photoconductor 20 is in the end state. If it is determined that the photoconductor 20 is in the end state (“YES” at S35), the operation proceeds to S36 to include notification that the photoconductor 20 is in the end state in the supply information screen, and further to S40. If it is determined that the photoconductor 20 is not in the end state (“NO” at S35), the operation proceeds to S37.

S37 determines whether photoconductor supply information indicates that the photoconductor 20 is in the near end state. If it is determined that the photoconductor 20 is in the near end state (“YES” at S37), the operation proceeds to S38 to include notification that the photoconductor 20 is in the near end state in the supply information screen, and further to S40. If it is determined that the photoconductor 20 is not in the near end state (“NO” at S37), the operation proceeds to S39.

S39 determines to include the supply amount information in the supply information screen.

S40 analyzes supply information and display settings information, which are obtained for the toner cartridge 22.

S41 determines whether the display/undisplay information is set to “UNDISPLAY”. If the display/undisplay information is set to “UNDISPLAY” (“YES” at S41), the operation proceeds to S42 to determine not to include the toner supply information in the supply information screen, and the operation ends. If the display/undisplay information is set to “DISPLAY” (“NO” at S41), the operation proceeds to S43.

S43 determines whether legitimacy information for the toner cartridge 22 is set to “NO”, i.e., the toner cartridge 22 is determined to be the illegitimate product. If legitimacy information is set to “NO” (“YES” at S43), the operation proceeds to S44 to determine to include notification that the toner cartridge 22 is not legitimate in the supply information screen, and the operation ends. If legitimacy information is set to “YES” (“NO” at S43), the operation proceeds to S45.

S45 determines whether toner supply information indicates that the toner cartridge 22 is in the end state. If it is determined that the toner cartridge 22 is in the end state (“YES” at S45), the operation proceeds to S46 to include notification that the toner cartridge 22 is in the end state in the supply information screen, and the operation ends. If it is determined that the toner cartridge 22 is not in the end state (“NO” at S45), the operation proceeds to S47.

S47 determines whether toner supply information indicates that the toner cartridge 22 is in the near end state. If it is determined that the toner cartridge 22 is in the near end state (“YES” at S47), the operation proceeds to S48 to include notification that the toner cartridge 22 is in the near end state in the supply information screen, and the operation ends. If it is determined that the toner cartridge 22 is not in the near end state (“NO” at S47), the operation proceeds to S49.

S49 determines to include the toner amount information in the supply information screen, and the operation ends.

The supply information screen generated according to the display settings information may be further edited using character information stored in the character table memory 124 (FIG. 6) or layout information stored in the layout information memory 125 (FIG. 6). The supply information screen may be further stored in the supply screen memory 126 (FIG. 6).

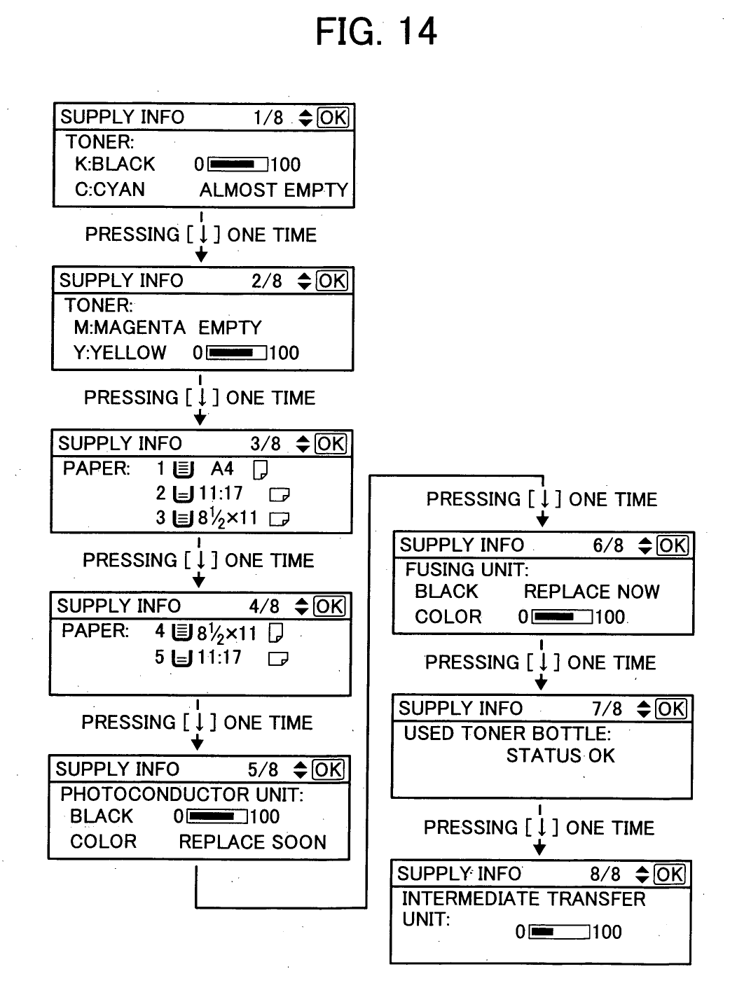

FIG. 14 illustrates an example supply information screen displayed by the operation panel 4 of FIG. 1. The supply information screen including the updated supply information of one or more printer supplies may be displayed automatically when updating of supply information is detected, or upon receiving a request for displaying from the user. The supply amount information, i.e., the remaining amount, may be displayed as the bar graph. Alternatively, as shown in the case of used toner bottle, the supply amount information may be displayed as the corresponding message, such as “Status OK”. When the remaining amount indicates that the printer supply is in the near end state, the corresponding message such as “Almost Empty”, “Replace Soon”, or “Almost Full”, may be displayed. When the remaining amount indicates that the printer supply is in the end state, the corresponding message such as “Empty”, “Replace Now”, or “Full”, may be displayed. When the printer supply is determined to be the illegitimate product, the icon shown in FIG. 16, or the corresponding message may be displayed.

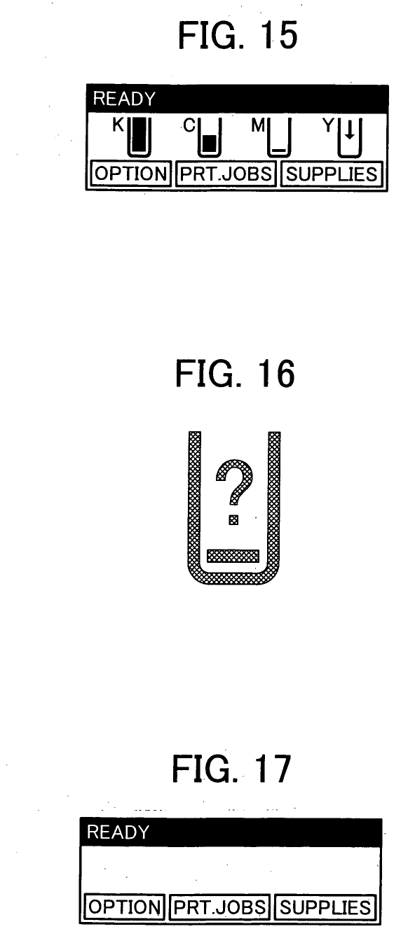

FIG. 15 illustrates an example supply information screen displayed by the operation panel 4 of FIG. 1. In this example, the supply information screen including updated supply information of the toner cartridge 22 is displayed when the printer 1 is in a waiting state. The supply amount information, i.e., the remaining toner amount for each one of the respective colors of black, cyan, magenta, and yellow, corresponds to the highlighted area of the icon. When the remaining toner amount indicates that the toner cartridge 22 is in the near end state, the icon may blink. When the remaining toner amount indicates that the toner cartridge 22 is in the end state, the arrow may be displayed. When the toner cartridge 22 is not the legitimate product, the icon shown in FIG. 16 may be displayed. Since the updated supply information is automatically displayed by the operation panel 4 as a wait screen, the user may easily obtain the updated supply information without inputting any instruction.

Further, the supply information screen of FIG. 15 may be provided with a “Supplies” key. When the “Supplies” key is selected, the supply information screen, i.e., the wait screen, of FIG. 15 may be switched to the supply information screen of FIG. 14.

In this manner, the user may obtain detailed information regarding one or more printer supplies at preferred timing.

Alternatively, the printer 1 may display a supply information screen shown in FIG. 17 when it is in a waiting state. The supply information screen of FIG. 17 includes the “Supplies” key, but not the updated supply information.

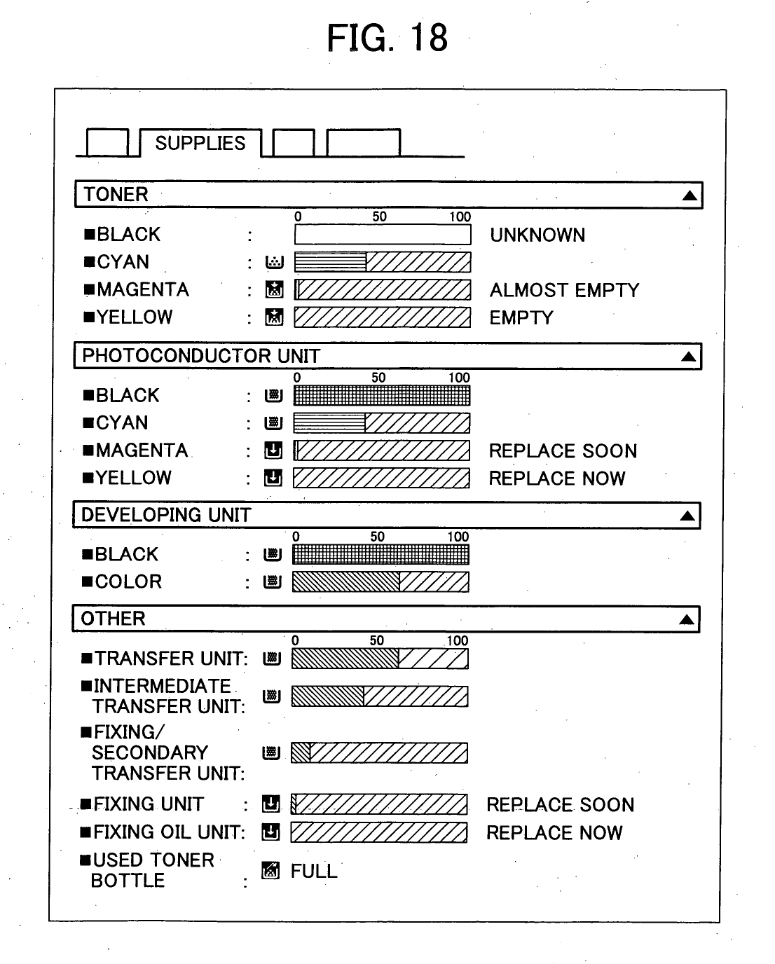

FIG. 18 illustrates an example supply information screen displayed by either one of the display device provided with the host apparatus 3 or a network apparatus existed on the network 15. The supply information screen shown in FIG. 18 may be displayed when the user instructs the printer 1 to display the updated supply information, for example, using an input device such as a mouse or a keyboard provided with the host apparatus 3 or the network apparatus. Alternatively, the supply information screen shown in FIG. 18 may be displayed when the corresponding program stored in the host apparatus 3 or the network apparatus is activated. Alternatively, a key having the function similar to the function of the “Supplies” key of FIG. 15 or 17 may be displayed first on the display device. When the key is selected by a user, the supply information screen shown in FIG. 18 may be displayed.

As described above referring to FIG. 15 or 17, the printer 1 may display the “Supplies” key, which allows the user to select whether to display the supply information screen shown in FIG. 14. In operation, upon receiving notification from the printer engine 13 that updating of supply information is detected, the system management module 320 sends a request for displaying the “Supplies” key, to the display module 110 or 120 via the UI I/F 200. Upon receiving the request for displaying the “Supplies” key, the display module 110 or 120 generates a supply information screen including the “Supplies” key shown in FIG. 15 or 17 for display. Alternatively, the “Supplies” key may have the appearance different from the appearance shown in FIG. 15 or 17, as long as it has the function of allowing the user to select whether to display the supply information screen of FIG. 14. Alternatively, the display module 110 or 120 may display a notification message, which notifies the user that supply information is updated, in any desired form, as long as it has the function of notifying the user that supply information is updated.

As described above referring to FIG. 12, the contents or appearance of the supply information screen, or timing for displaying the supply information screen, may be changed according to the user preference, by allowing the user to update the display settings information stored in the supply management table 331.

For example, upon receiving a request for updating display settings information, the system management module 320 may cause the information management module 330 to update the display settings information stored in the supply management table 331. After updating the display settings information, the system management module 320 sends a request for displaying the updated display settings information, to the display module 110 or 120 via the UI I/F 200. Upon receiving the request for displaying, the display module 110 or 120 generates a display settings screen including the updated display settings information in the form applicable to the corresponding display device, and displays the display settings screen.

In this example, as illustrated in FIG. 13, timing for displaying the supply information screen may be changed by updating the display/undisplay information, end display/undisplay information, or near end display/undisplay information. For example, when the user prefers to be notified only when the printer supply is in the end state, the end display/undisplay information is set to “DISPLAY” while the display/undisplay information for the other state is set to “UNDISPLAY”. When the user prefers to be notified only when the printer supply is in the near end state, the near end display/undisplay information is set to “DISPLAY” while the display/undisplay information for the other state is set to “UNDISPLAY”. When the user prefers to be notified when the printer supply is in the near end state and the end state, the end display/undisplay information and the near end display/undisplay information are both set to “DISPLAY”, while the display/undisplay information for the other state is set to “UNDISPLAY”. When the user prefers to be notified every time the supply information is updated, the display/undisplay information is set to “DISPLAY”.

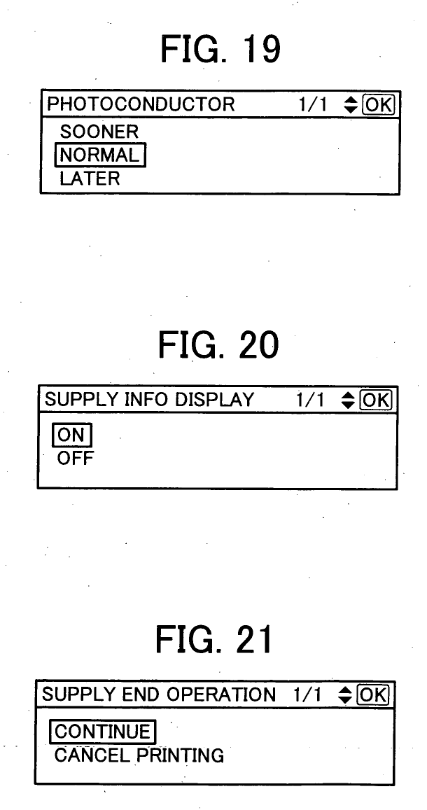

Alternatively, timing for displaying the supply information screen may be changed by adjusting the reference level used for determining whether the printer supply is in the near end state. For example, as illustrated in FIG. 19, the operation panel 4 may display a display settings screen, which allows the user to change the reference level used for determining whether the photoconductor 20 is in the near end state. The user may select one of the options listed on the display setting screen. In this example, when the “sooner” option is selected, the reference level for determining whether the photoconductor 20 is in the near end state is set to 9500 revolutions. When the “normal” option is selected, the reference level for determining whether the photoconductor 20 is in the near end state is set to 10,000 revolutions. When the “later” option is selected, the reference level for determining whether the photoconductor 20 is in the near end state is set to 10,500 revolutions.

Further, in this example, the contents of the supply information screen may be changed by updating the supply name, display/undisplay information, or legitimacy information. In this manner, supply information of more than one printer supply may be displayed at once, for example, as illustrated in FIG. 14 or 18.

Alternatively, as described above referring to FIGS. 15 and 17, the user may select whether to include the updated supply information in the wait screen. For example, as illustrated in FIG. 20, the operation panel 4 may display a display settings screen, which allows the user to select whether to display the updated supply information in the wait screen. When the “ON” option is selected, the operation panel 4 displays the updated supply information in the wait screen. When the “OFF” option is selected, the operation panel 4 does not display the updated supply information in the wait screen.

Alternatively, the contents or appearance of the supply information screen or timing for displaying the supply information screen may be set differently among users.

For example, the supply management table 331 may additionally store user ID information. Alternatively, a user ID table storing the user ID information may be provided in a manner manageable by the information management module 330. By storing supply information and/or display/undisplay information in a corresponding manner with the user ID information, the contents or appearance of the supply information screen or timing for displaying the supply information screen may be set specific to the need of each user. Further, this function may be used to restrict a selected user group from viewing some information. The user ID information may be input by the user. Alternatively, the user ID information may be read out from a removable medium.

Further, in this example, the printer 1 may allow the user to determine whether to continue or cancel a current job when updating of supply information is detected.

For example, the printer 1 may allow the user to determine whether to continue or cancel a printing job when the printer supply is determined to be in the end state. For example, as illustrated in FIG. 21, the operation panel 4 may display a printing settings screen, which allows the user to select whether to continue or cancel a printing job currently performed when the end state of the printer supply is detected.

Alternatively, the printer 1 may allow the user to determine whether to continue or cancel a current job, by displaying notification to the user. For example, when the end state of the printer supply is detected by the printer engine 13, the system management module 320 determines whether the printer 1 is currently performing a printing job. When it is determined that the printing job is currently performed, the system management module 320 sends a request for stopping the printing job to the printer engine 13 through the engine management module 340. The system management module 320 may further send a request for displaying notification, such as a screen including the “CONTINUE” button and the “CANCEL” button, to the display module 110 or 120 via the UI I/F 200.

Alternatively, the printer 1 may continue a current job even when updating of supply information is detected. For example, the printer 1 may continue a printing job even when the end state of the printer supply is detected, as long as it is determined that the printer job can be performed. In such case, the display panel 4 may just switch a printing screen displayed when performing the printing job, to the supply information screen, without interrupting the printing job. The printing screen may be stored in the previous screen memory 127 of FIG. 6. Further, the timer 350 may be initialized to count a time period after the printing screen is switched to the supply information screen. When the counted time period reaches a predetermined time period, the supply information screen is switched back to the printing screen. In this manner, the printing job may be performed without being interrupted.

Alternatively, in the case of continuing the printing job even when the supply information is updated, the printer 1 may wait to display the supply information screen until the printing job is completed. When the printing job is completed, the printer 1 may update the supply information stored in the supply management table 331 again, and generates a supply information screen including the updated supply information for display. In this manner, the supply information that reflects the state of the printer 1 after completing the printing job may be easily obtained.

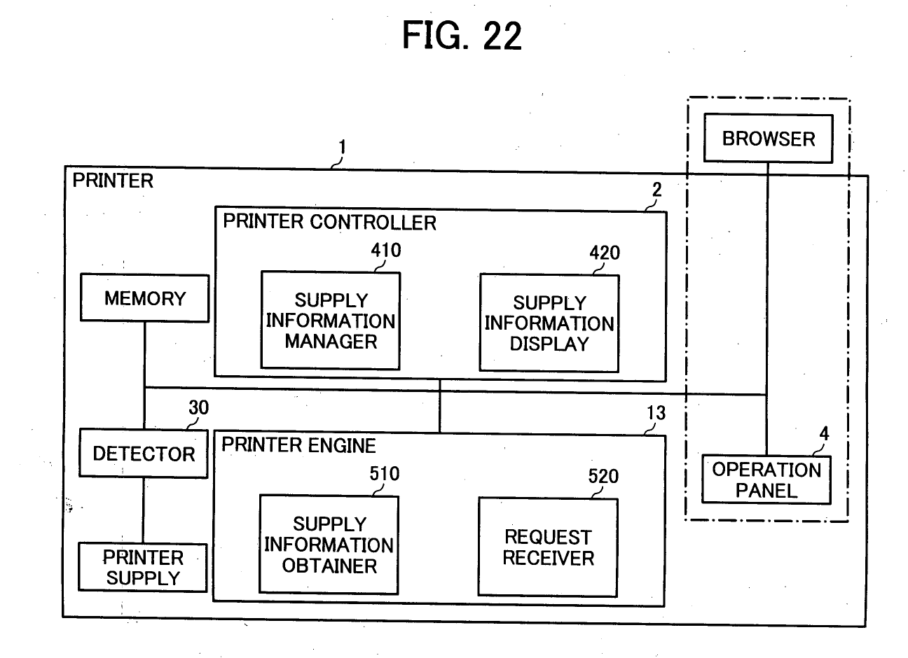

Referring to FIG. 22, the functional structure of the printer 1 is explained according to an example embodiment of the present invention.

As described above, the printer controller 2 includes the functions of managing supply information (“supply information manager 410”), and displaying supply information (“supply information display 420”). The printer engine 13 includes the functions of obtaining supply information from the detector 30 (“supply information obtainer 510”), and receiving a request for supply information (“request receiver 520”).

In example operation, the detector 30 detects supply information of the printer supply, i.e., supply information of the image forming device. The detected supply information may be stored in a memory. When the detected supply information is updated, the printer engine 13 sends notification to the printer controller 2. Upon receiving notification, the printer controller 2 sends a request for obtaining the updated supply information to the printer engine 13. Once the request is received by the request receiver 520, the supply information obtainer 510 obtains the updated supply information, and sends the updated supply information to the printer controller 2. The supply information manager 410 updates the supply information with the updated supply information. The supply information display 420 generates an information supply screen including the updated supply information according to display settings information, which may be stored in the memory. The information supply screen may be further sent to a browser, such as a web browser installed on the host apparatus 3 or the network apparatus existed on the network 15, or to the operation panel 4, for display at timing specified by the display settings information.

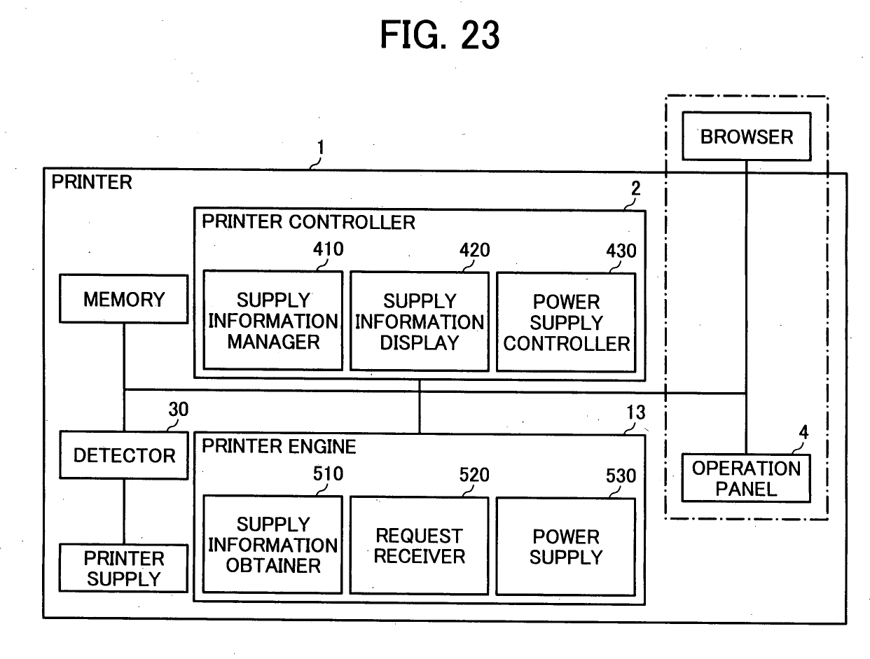

In addition to the functions illustrated in FIG. 22, the printer 1 of FIG. 1 may be provided with the function of controlling electric power supplied to the detector 30, for example, as illustrated in FIG. 23.

Referring to FIG. 23, the printer controller 2 is additionally provided with the function of controlling electric power supplied to the printer engine 13 (“power supply controller 430”). The power supply controller 430 may include a timer, which counts a time period from predetermined timing to output a counted time period. In one example, the predetermined timing may be set to timing when a job requested by a user is completed. The printer engine 13 is additionally provided with the function of supplying electric power to a selected portion of the printer engine 13 under control of the power supply controller 430 (“power supply 530”).

In operation, when the counted time period obtained by the timer reaches a predetermined time period, or when a user instruction for switching to an energy save mode is received through the browser or the operation panel 4, the power supply controller 430 instructs the power supply 530 to turn off electric power supplied to the printer engine 13 to cause the printer 1 to be in the energy save mode. When the user instruction for switching from the energy save mode to the operation mode is received through the browser or the operation panel 4, the power supply controller 430 instructs the power supply 530 to turn on the electric power supplied to the printer engine 13 to cause the printer 1 to be in the operation mode.

Further, in this example, when a request for displaying supply information is received through the browser or the operation panel 4, the power supply controller 430 determines whether the printer 1 is in the energy save mode. When it is determined that the printer 1 is in the energy save mode, the power supply controller 430 sends a request for turning on the electric power supplied to the detector 30, to the printer engine 13. Upon receiving the request, the power supply 530 turns on the electric power supplied to the detector 30. Since the electric power is supplied to the detector 30, the printer engine 13 is able to obtain supply information detected by the detector 30, and output the updated supply information to the printer controller 2 for display. After the updated supply information is displayed, the power supply controller 430 may send a request for turning off the electric power supplied to the detector 30, to the printer engine 13. Upon receiving the request, the power supply 530 turns off the electric power supplied to the detector 30 to cause the printer to return to the energy save mode. In this manner, the printer 1 may display the updated supply information in a timely manner upon receiving a request for displaying supply information, while suppressing energy consumption.

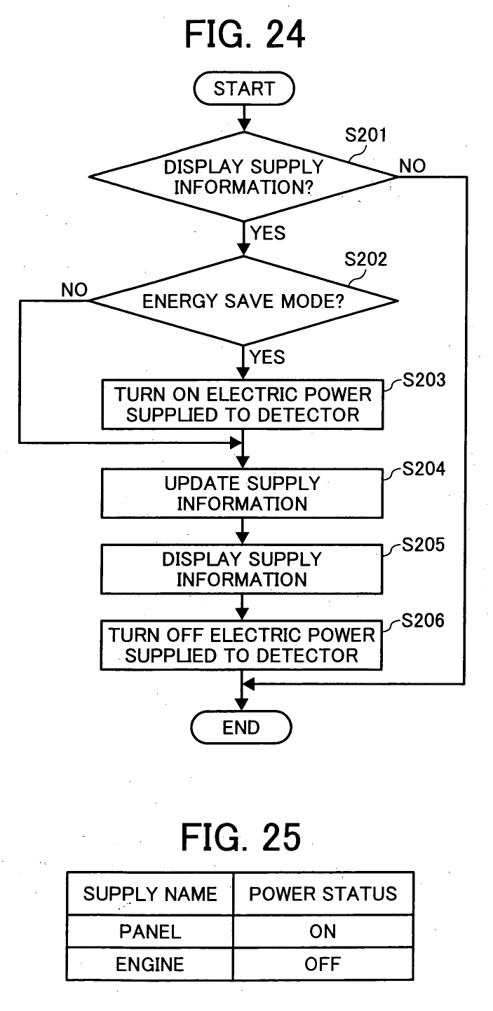

Referring now to FIG. 24, an example operation of displaying supply information is explained. In this example, the printer controller 2 may have the software structure substantially similar to the structure shown in FIG. 5. In such case, the operation of FIG. 24 may be performed by the printer management module 300 of FIG. 5.

S201 determines whether to display supply information. In this example, the printer management module 300 determines to perform operation of displaying supply information when a request for displaying supply information is received from the outside process 100, such as a user instruction received through the display module 110 or 120. If it is determined to perform operation of displaying (“YES” at S201), the operation proceeds to S202. Otherwise (“NO” at S201), the operation ends.

S202 determines whether the printer 1 is in the energy save mode. For example, the printer controller 2 may store power supply information indicating which portion of the printer 1 is turned on, for example, as illustrated in FIG. 25, in addition to supply information or display settings information described above. In FIG. 25, the panel corresponds to the operation panel 4, and the engine corresponds to the printer engine 13. When the power status of the panel and the power status of the engine are both set to “ON”, the printer 1 is determined to be in the operation mode. When the power status of the panel is set to “ON”, and the power status of the engine is set to “OFF”, the printer 1 is determined to be in the energy save mode. In this manner, the mode of the printer 1 may be detected. If the power supply information indicates that the printer 1 is in the energy save mode (“YES” at S202), the operation proceeds to S203. If the power supply information indicates that the printer 1 is in the operation mode (“NO” at S202), the operation proceeds to S204.

S203 turns on the electric power supplied to the detector 30. For example, the system management module 310 may send a request for turning on the electric power, to the printer engine 13. Upon receiving the request, the printer engine 13 turns on the electric power supplied to the detector 30. In this manner, the printer 1 is caused to switch to a state in which updated supply information can be obtained while suppressing the power consumption.

S204 updates the supply information stored in the supply management table 331 in a substantially similar manner as described above referring to S102 of FIG. 7. Further, at S204, the printer controller 2 may store the updated supply information.

S205 displays the supply information in a substantially similar manner as described above referring to S103 of FIG. 7.

S206 turns off the electric power supplied to the detector 30, and the operation ends. For example, after the updated supply information is displayed, the system management module 310 may send a request for turning off the electric power supplied to the detector 30, to the printer engine 13. Upon receiving the request, the printer engine 13 turns off the electric power supplied to the detector 30.

The operation of FIG. 24 may be performed in various other ways. For example, before performing S204, the printer controller 2 may determine whether updating of supply information is necessary. When it is determined that updating of supply information is necessary, the printer controller 2 performs S204 to update supply information. When it is determined that updating of supply information is not necessary, the printer controller 2 may obtain supply information stored in the supply management table 331.

In another example, before performing S204, the printer controller 2 may determine whether to obtain supply information according to display settings information, such as display/undisplay information, for example, as described above referring to S2 of FIG. 8. When it is determined to obtain supply information, the printer controller 2 performs S204 to update supply information. When it is determined not to obtain supply information, the printer controller 2 may end the operation, notifying the user that supply information is not available.

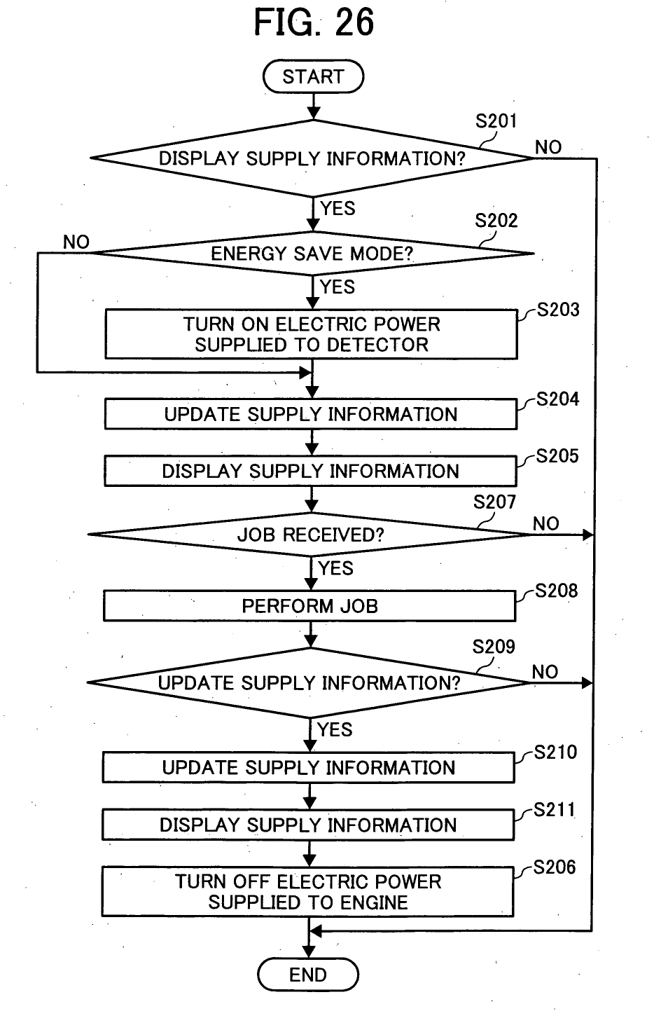

Referring now to FIG. 26, an example operation of displaying supply information is explained. The operation of FIG. 26 is substantially similar to the operation of FIG. 24, except for the addition of S207, S208, S209, S210, and S211.

After displaying the updated supply information, S207 determines whether a request for performing a job is received. When the request for performing the job is received (“YES” at S207), the operation proceeds to S208. Otherwise (“NO” at S207), the operation proceeds to S206.

S208 performs the requested job. In this example, when the request job including a printing job is received, the electric power supplied to the printer engine 13 is turned on. In another example, when the request job including storing data, the electric power supplied to the printer engine 13 may not be turned on as long as the electric power is supplied to the printer controller 2.

S209 determines whether the supply information stored in the supply management table 331 needs to be updated. If the supply information needs to be updated (“YES” at S209), the operation proceeds to S210 to update the supply information. Otherwise (“NO” at S209), the operation proceeds to S206. For example, when the printing job is performed at S208, it may be determined that the supply information needs to be updated.

S210 updates the supply information in a substantially similar manner as described above referring to S204 of FIG. 24. At S210, the updated supply information may be stored.

S211 displays the updated supply information, which reflects the state of the printer 1 after performing the requested job.

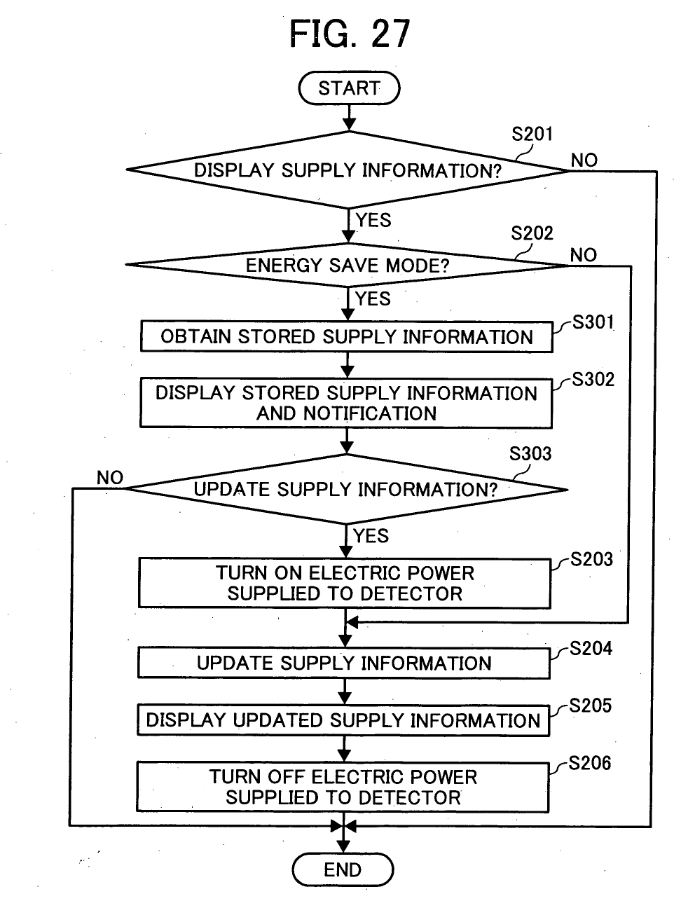

Referring now to FIG. 27, an example operation of displaying supply information is explained. The operation of FIG. 27 is substantially similar to the operation of FIG. 25. The differences include the addition of S301, S302, and S303.

When it is determined that the printer 1 is in the energy save mode at S202 (“YES” at S202), the operation proceeds to S301 to obtain supply information stored in the supply management table 331. At this time, the printer controller 2 obtains the most updated supply information obtainable from the supply management table 331, without causing the printer engine 13 to turn on the electric power supplied to the detector 30. In this manner, electric consumption may be suppressed. The most updated supply information may correspond to the supply information obtained when the last printing job is performed. Alternatively, the most updated supply information may correspond to the supply information obtained just before the electric power supplied to the detector 30 is turned off.

S302 displays the stored supply information according to the display settings information. At this time, the printer controller 2 causes the display device to display notification to the user that the obtained supply information may not reflect the latest information obtainable from the detector 30. In addition, the printer controller 2 may cause the display device to display a selection key, which allows the user to select whether to update the supply information. If the user prefers to update, the user may input a user instruction for updating by selecting the selection key.

S303 determine whether to update supply information according to the user instruction input at S302. If the user instruction requesting for updating is input at S302 (“YES” at S303), the operation proceeds to S203 to turn on the electric power supplied to the detector 30. Otherwise (“NO” at S303), the operation ends.

The operation of FIG. 27 may be performed in various other ways. For example, before performing S206 of running off the electric power supplied to the detector 30, the printer controller 2 may determine whether a request for job is performed.

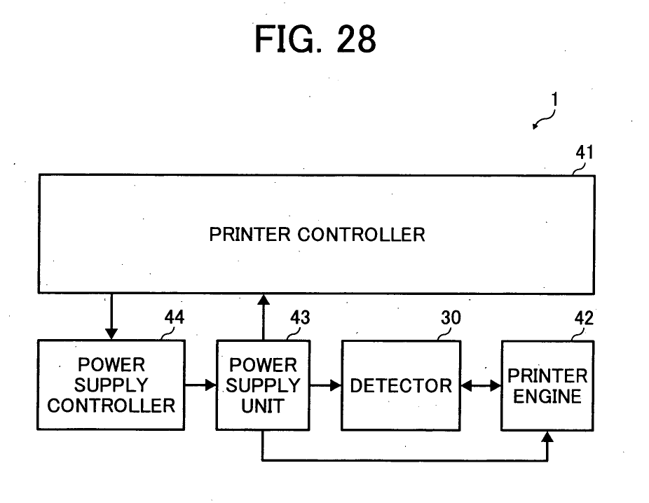

In alternative to the hardware structure shown in FIG. 1, in order to perform operation of controlling electric power supplied to the printer engine 13, the printer 1 of FIG. 23 may be implemented in a different way, for example, as illustrated in FIG. 28.

Referring to FIG. 28, the printer 1 includes a printer controller 41, a printer engine 42, the detector 30, a power supply unit 43, and a power supply controller 44. The printer controller 41 is substantially similar in hardware structure to the printer controller 2. The differences include that the function performed by the power supply controller 430 (FIG. 23) is performed by the power supply controller 13. The printer engine 42 is substantially similar in hardware structure to the printer engine 13. The differences include that the function performed by the power supply 530 (FIG. 23) is performed by the power supply unit 43. In this example, the detector 30 is provided separately from the printer engine 42. Alternatively, the detector 30 may be incorporated in the printer engine 42.

When the printer 1 is in the operation mode, the power supply unit 43 turns on the electric power supplied to the printer engine 42 and the electric power supplied to the detector 30. When the printer 1 is in the energy save mode, the power supply controller 41 causes the power supply unit 43 to turn off the electric power supplied to the printer engine 42 and the electric power supplied to the detector 30. When the printer controller 41 receives a request for displaying supply information, for example, from the operation panel 4, the printer controller 41 outputs a control signal to the power supply controller 44. Upon receiving the control signal, the power supply controller 44 causes the power supply unit 43 to turn on the electric power supplied to the detector 30.

Numerous additional modifications and variations are possible in light of the above teachings. It is therefore to be understood that within the scope of the appended claims, the disclosure of this patent specification may be practiced in ways other than those specifically described herein.

For example, elements and/or features of different illustrative embodiments may be combined with each other and/or substituted for each other within the scope of this disclosure and appended claims.

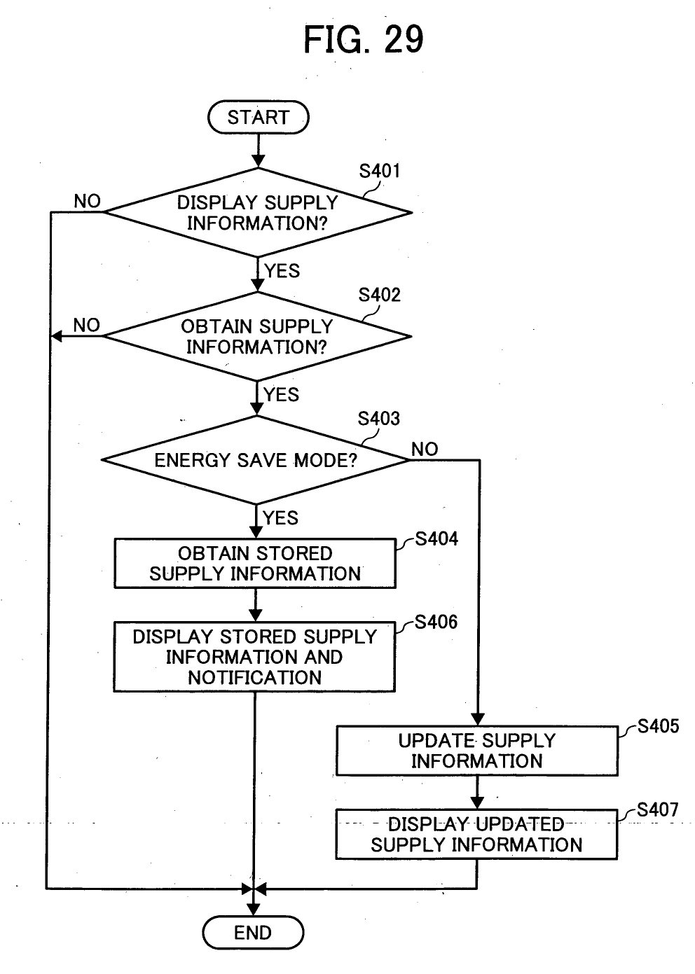

Referring to FIG. 29, an example operation of displaying supply information, performed by the printer controller 2, is explained according to an example embodiment of the present invention. In this example, the printer controller 2 is assumed to store supply information of an image forming device, display settings information, and power supply information, in a form manageable by the printer controller 2. For example, such information may be stored as flag information.

S401 determines whether to display supply information. In one example, the printer controller 2 determines to perform operation of displaying supply information when notification is received from the printer engine 13 that supply information is updated. In another example, the printer controller 2 determines to perform operation of displaying supply information when a request for displaying is received from the outside, such as a user instruction received through the operation panel 4 or the host apparatus 3. If it is determined to perform operation of displaying (“YES” at S401), the operation proceeds to S402. Otherwise (“NO” at S401), the operation ends.

S402 determines whether to obtain supply information based on the display settings information. If the display/undisplay information indicates to display the supply information (“YES” at S402), the operation proceeds to S403. If the display/undisplay information indicates not to display the supply information (“NO” at S402), the operation ends to cause a display device to display an error message.

S403 determines whether update supply information is obtainable based on the power supply information. If the power supply information indicates that the printer 1 is in the energy save mode (“YES” at S403), the operation proceeds to S404. If the power supply information indicates that the printer 1 is in the operation mode (“NO” at S402), the operation proceeds to S405.

S404 obtains supply information, which is previously stored, without turning on the electric power supplied to the detector 30.

S405 updated supply information by obtaining supply information from the detector 30.

S406 generates a supply information screen including the stored supply information according to the display settings information, and displays the supply information screen. The supply information screen may further include notification that the supply information is not updated, and the operation ends.

S407 displays a supply information screen including the updated supply information according to the display settings information, and displays the supply information screen, and the operation ends.

The operation of FIG. 29 may be performed in various other ways. For example, at S406, the supply information screen may further request the user whether to update the stored supply information. In another example, the supply information screen generated for display at S407 may be stored.

Still referring to FIG. 29, when notification that supply information is updated is received at S401, it can be assumed that the electric power is supplied to the detector 30. Thus, the printer controller 2 automatically updates the supply information when updating of the supply information is detected by the detector 30. On the other hand, when a request for displaying supply information is received at S401, the electric power supplied to the detector 30 may not be turned on. Thus, the printer controller 2 may display the latest updated supply information, and further notify the user that the displayed supply information is not updated. In this manner, updated supply information may be automatically displayed to a user without consuming too much energy. Alternatively, whether to automatically display the updated supply information may be determined according to the user preference. For example, when the user prefers to save energy, the printer may be set such that it only displays the updated supply information upon receiving a request for updating the stored supply information.

Further, as described above, any one of the above-described and other methods of the present invention may be embodied in the form of a computer program stored in any kind of storage medium. Examples of storage mediums include, but are not limited to, flexible disk, hard disk, optical discs, magneto-optical discs, magnetic tapes, involatile memory cards, ROM (read-only-memory), etc. Further, any information used for managing supply information, such as supply information, display settings information, user ID information, or power supply information, may be stored in any desired memory with any desired format.

Further, operation of managing supply information may be performed by an image forming system, which includes an image forming device to be detected by a detector, and an image processing device for managing supply information of the image forming device obtained by the detector. In such case, the image forming device, the detector, and the image processing device may not be incorporated into one apparatus.

Alternatively, any one of the above-described and other methods of the present invention may be implemented by ASIC, prepared by interconnecting an appropriate network of conventional component circuits or by a combination thereof with one or more conventional general purpose microprocessors and/or signal processors programmed accordingly.

1. An image forming apparatus, comprising:
a detector configured to detect supply information of an image forming device provided in the image forming apparatus; and
a controller configured to store the supply information in a corresponding manner with display settings information, update the supply information to generate updated supply information when the controller receives notification that the supply information is updated, and generate a supply information screen comprising the updated supply information to be displayed on a display device according to the display settings information.

2. The apparatus of claim 1, wherein the controller is further configured to automatically display the supply information screen on the display device when the controller receives the notification that the supply information is updated.

3. The apparatus of claim 1, wherein the controller is further configured to automatically display a selection key on the display device, which allows a user to select whether to display the supply information screen, when the controller receives the notification that the supply information is updated.

4. The apparatus of claim 1, wherein the updated supply information comprises at least one of:
supply amount information indicating the amount of a supply of the image forming device;
near end supply status information indicating whether the image forming device is in the near end state;
end supply status information indicating whether the image forming device is in the end state; and
legitimacy information indicating whether the image forming device is a legitimate product.

5. The apparatus of claim 4, wherein the controller is further configured to determine whether the image forming device is in the near end state based on a reference level determined by a user.

6. The apparatus of claim 1, wherein the controller is further configured to store information regarding a previous screen displayed on the display device before the supply information screen is displayed on the display device, and cause the display device to switch from the supply information screen back to the previous screen after the supply information screen is displayed.

7. The apparatus of claim 1, wherein the controller is further configured to determine whether a request for performing an image forming job is received, and cause the display device to display the supply information screen after completion of the image forming job when the request for performing the image forming job is received.

8. The apparatus of claim 7, wherein the controller is further configured to update the updated supply information after completion of the image forming job when the request for performing the image forming job is received such that the supply information screen comprises the updated supply information obtained from the detector after completion of the image forming job.

9. The apparatus of claim 1, wherein the controller is further configured to display the supply information screen on the display device at timing when the controller receives a request for displaying the supply information.

10. An image forming apparatus, comprising:
a detector configured to detect supply information of an image forming device when electric power supplied to the detector is turned on; and
a controller configured to determine whether the electric power is turned on upon receiving a request for displaying the supply information to generate a first determination result, turn on the electric power when the first determination result indicates that the electric power is turned off, update the supply information to generate updated supply information, display a supply information screen comprising the updated supply information, and turn off the electric power after the supply information is displayed.

11. The apparatus of claim 10, wherein the controller is further configured to determine whether a request for performing a job is received, and when the request for performing the job is received, cause the apparatus to complete the job before the electric power supplied to the detector is turned off.

12. The apparatus of claim 11, wherein the controller is further configured to update the updated supply information after completion of the job when the request for performing the job comprises an image forming job.

13. An image forming apparatus, comprising:
a detector configured to detect supply information of an image forming device when electric power supplied to the detector is turned on; and
a controller configured to store the supply information, determine whether the electric power is turned on upon receiving a request for displaying the supply information to generate a determination result, obtain the stored supply information when the determination result indicates that the electric power is turned off, and display a supply information screen comprising the stored supply information and notification notifying a user that the supply information is not updated.

14. The apparatus of claim 13, wherein the supply information screen further comprises a selection key allowing the user to select whether to update the supply information.

15. A method of displaying supply information of an image forming apparatus, the method comprising:
storing supply information of an image forming device provided in the image forming apparatus, display settings information previously set for the supply information of the image forming device, and power supply information indicating whether the apparatus is in an energy save mode;
receiving a request for displaying the supply information or notification that updated supply information is detected;
determining whether the updated supply information is obtainable based on the power supply information to generate a first determination result;
determining whether to obtain the updated supply information for display based on the display settings information to generate a second determination result;
obtaining the updated supply information when the first determination result indicates that the apparatus is not in the energy save mode and when the second determination result indicates that the supply information is to be displayed; and
generating a first supply information screen comprising the updated supply information when the first determination result indicates that the apparatus is not in the energy save mode and when the second determination result indicates that the supply information is to be displayed.

16. The method of claim 15, further comprising:
displaying the first supply information screen at timing when the notification that the updated supply information is detected, when the notification that the updated supply information is received and when the display settings information is set to automatically display the updated supply information.

17. The method of claim 15, further comprising:
obtaining the stored supply information when the first determination result indicates that the apparatus is in the energy save mode and when the second determination result indicates that the supply information is to be displayed; and
generating a second supply information screen comprising the stored supply information when the first determination result indicates that the apparatus is in the energy save mode and when the second determination result indicates that the supply information is to be displayed.

18. The method of claim 17, further comprising:
displaying the second supply information screen at timing when the request for displaying the supply information is received, when the request for displaying the supply information is received.

19. The method of claim 18, wherein the second supply information screen further comprises a selection key allowing the user to select whether to update the stored supply information,
the method further comprising:
obtaining the updated supply information by causing the apparatus to switch from the energy save mode to a state in which the updated supply information is obtainable;
displaying a third supply information screen comprising the updated supply information; and
causing the apparatus to switch back to the energy save mode.

20. The method of claim 19, further comprising:
determining whether a request for performing a job is received before the apparatus is caused to switch back to the energy save mode.
